(19) United States
(12) Patent Application Publication
(10) Pub. No.: US 2012/0133258 A1
(43) Pub. Date: May 31, 2012

(54) DOOR MECHANISM FOR SECURE DIGITAL MEMORY CARD

(76) Inventors: GIANCARLO GIUSTINA, San Francisco, CA (US); Karla Robertson, Woodside, CA (US); William A. Saperstein, San Carlos, CA (US)

(21) Appl. No.: 13/245,686

(22) Filed: Sep. 26, 2011

Related U.S. Application Data
(60) Provisional application No. 61/406,795, filed on Oct. 26, 2010.

(51) Int. Cl. H05K 5/03; E05C 17/56; E06B 3/34

(52) U.S. Cl. 312/326; 49/394

(57) ABSTRACT

A door assembly for enclosing a compartment of a portable electronic device. The door assembly includes a door cover, operable to selectively provide access to the compartment, anchors, affixed to the door cover, configured to retain the door in a cover portion of the portable electronic device, and a permanent magnet, disengageably mounted in the door cover, the permanent magnet operable to maintain the door in a closed state with respect to the compartment.

### CROSS REFERENCE TO RELATED APPLICATION

This application claims benefit under 35 U.S.C. §119(e) from U.S. Provisional Patent application No. 61/406,795, filed on Oct. 26, 2010, the entirety of which is incorporated by reference herein.

### FIELD OF THE INVENTION

The present invention generally relates to door mechanisms, and more particularly to a door mechanism for a compartment in a portable electronic device, such as a compartment for a Secure Digital (SD) memory card tray.

### SUMMARY OF THE INVENTION

In accordance with a first aspect of the present invention, there is provided a door assembly for enclosing a compartment of a portable electronic device. The door assembly includes: a door cover, operable to selectively provide access to the compartment; anchors, affixed to the door cover, configured to retain the door in a cover portion of the portable electronic device; and a permanent magnet, disengageably mounted in the door cover, that tends to maintain the door in a closed state with respect to the compartment.

In another aspect, the anchors comprise lengthwise protrusions associated with the door cover that prevent the door cover from completely disengaging from the cover portion of the portable electronic device.

In another aspect, the anchors are formed from an elastic material.

In another aspect, the disengageably mounted permanent magnet in the door cover tends to maintain the door in a closed state by magnetic attraction to another permanent magnet located in the cover portion of the portable electronic device.

In another aspect, the anchors comprise bumps formed on a portion proximal to the door cover, the bumps forming detents that contact and impart a frictional force to a recessed portion of the cover portion when the door cover is in a closed state with respect to the compartment.

In another aspect, the anchors comprise barbed ends formed on a portion distal to the door cover, the barbed ends maintaining the door assembly in the cover portion when the door cover is in an open state.

In another aspect, the recessed portion comprises apertures in the back cover.

In another aspect, the anchors have a substantially flat profile and mate with apertures formed in the housing.

In another aspect, the device further comprises a frame around a periphery of the cover portion, an inner portion of the frame comprising dimples tending to hold the door cover in the closed state.

In another aspect, the device further comprises a frame around a periphery of the cover portion, the door assembly being located within a gap formed between the frame and a corner of the cover portion.

In another aspect, the compartment houses one from among the group consisting of an memory SD card, a SIM card and a battery.

In another aspect, the anchors are formed of a single piece of elastic material affixed to the door cover.

In another aspect, the anchors are substantially completely within the cover portion when the door is in the closed state and partially withdrawn from the cover portion when the door is in the open state.

In another aspect, the anchors are positioned on the door cover so as to be placed on either side of the compartment.

In another aspect, the disengageably mounted permanent magnet in the door cover and the permanent magnet located in the cover portion of the portable electronic device are aligned with one another when the door is in a closed state and the magnetic attraction between them maintains the door in the closed state by magnetic attraction.

In another aspect, an opening in each of the anchors between the bumps facilitates the anchors to compress when the door is being opened or closed.

In accordance with a second aspect of the present invention, there is provided a housing for a portable electronic device, the housing including: a cover portion of the portable electronic device forming at least a substantial part of a surface of the portable electronic device; a rim formed around a periphery of the cover portion, a gap being formed between the cover portion and the rim at least one point along the periphery; a compartment formed in the cover portion; and a door assembly for selectively enclosing the compartment. The door assembly includes: a door cover, operable to selectively provide access to the compartment; anchors, affixed to the door cover, configured to retain the door in a cover portion of the portable electronic device; and a permanent magnet, disengageably mounted in the door cover, that tends to maintain the door in a closed state with respect to the compartment.

In another aspect, the anchors comprise lengthwise protrusions associated with the door cover that prevent the door cover from completely disengaging from the cover portion of the portable electronic device.

In another aspect, the anchors are formed from an elastic material.

In another aspect, the disengageably mounted permanent magnet in the door cover tends to maintain the door in a closed state by magnetic attraction to another permanent magnet located in the cover portion of the portable electronic device.

In another aspect, the anchors comprise bumps formed on a portion proximal to the door cover, the bumps forming detents that contact and impart a frictional force to a recessed portion of the cover portion when the door cover is in a closed state with respect to the compartment.

In another aspect, the anchors comprise barbed ends formed on a portion distal to the door cover, the barbed ends maintaining the door assembly in the cover portion when the door cover is in an open state.

In another aspect, the recessed portion comprises apertures in the back cover.

In another aspect, the anchors have a substantially flat profile and mate with apertures formed in the housing.

In another aspect, an inner portion of the frame comprises dimples tending to hold the door cover in the closed state.

In another aspect, the door assembly is located within a gap formed between the frame and a corner of the cover portion.

In another aspect, the compartment houses one from among the group consisting of an memory SD card, a SIM card and a battery.

In another aspect, the anchors are formed of a single piece of elastic material affixed to the door cover.

In another aspect, the anchors are substantially completely within the cover portion when the door is in the closed state and partially withdrawn from the cover portion when the door is in the open state.

In another aspect, the anchors are positioned on the door cover so as to be placed on either side of the compartment.

In another aspect, the disengageably mounted permanent magnet in the door cover and the permanent magnet located in the cover portion of the portable electronic device are aligned with one another when the door is in a closed state and the magnetic attraction between them maintains the door in the closed state by magnetic attraction.

In another aspect, an opening in each of the anchors between the bumps facilitates the anchors to compress when the door is being opened or closed.

In accordance with a third aspect of the present invention, there is provided a door assembly for enclosing a compartment of a portable electronic device, the door assembly including: a door cover, operable to selectively provide access to the compartment by partial detachment of the door cover from the compartment; anchors, affixed to the door cover, configured to retain the door in a cover portion of the portable electronic device, the anchors including bumps along outer edges of each anchor to provide a frictional force to tend to maintain the door in a closed state with respect to the compartment; and a permanent magnet, disengageably mounted in the door cover, that tends to maintain the door in a closed state with respect to the compartment. The door cover is operable to be changed from the closed state to an open state by application of upward pressure, by a user to the door cover, of sufficient force to overcome the maintaining forces provided by the bumps and the permanent magnet.

### BRIEF DESCRIPTION OF THE DRAWINGS

For the purposes of illustrating the present invention, there is shown in the drawings a form which is presently preferred, it being understood however, that the invention is not limited to the precise form shown by the drawing in which:

FIG. 1 is a plan view of the back cover of a portable electronic device incorporating the door in accordance with an aspect of the present invention;

FIGS. 2A-2D depict the door in the closed and open status;

FIGS. 3A-3B further illustrate the operation of the opening of the door;

FIG. 4 is a partial cross section of the door in a closed state;

FIGS. 5A-5C illustrate the magnet assembly of the present invention;

FIG. 6 illustrates the configuration of the magnets forming the magnet assembly, when the door is in a closed state;

FIG. 7 is a cross section view of the door in a closed state;

FIG. 8 further illustrates details of the door anchors;

FIG. 9 is a further view of the structure of the door anchors;

FIG. 10 is a further view showing the apertures in the back cover; and

FIG. 11 depicts projections formed on the frame in the lanyard loop area.

### DETAILED DESCRIPTION OF THE INVENTION

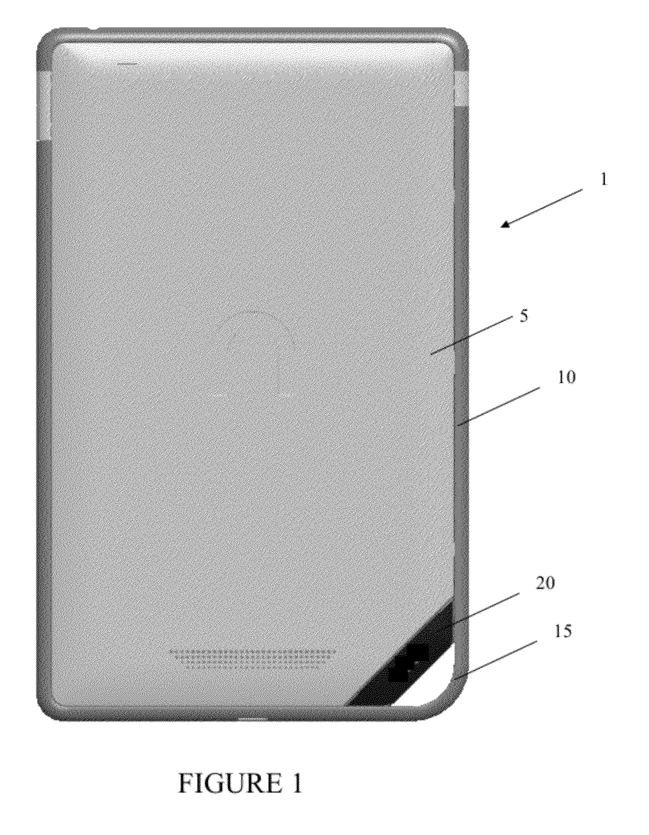

FIG. 1 illustrates a plan view of the back cover 5 of a portable electronic device 1 incorporating the door 20 of the present invention. The device 1 has a frame 10. A loop 15 is formed in the frame surrounding a gap 4 in the back cover 5. This gap 4 provides easy access for opening and closing the door 20. The loop 15 also prevents inadvertent operation of the door. This loop 15 can also act as an attachment point for a lanyard or other fastener device for securing and/or carrying the device 1.

Although throughout the illustrated embodiments the door 20 is depicted as facing this gap in the back cover, the door 20 disclosed in the present application is not limited to being provided at a corner location, or in relation to a gap in a frame of a device. As would be appreciated by those of skill in the art, the illustrated components and configuration of the door in accordance with the disclosed aspects of the present invention is also suitable to be located at other positions on the device 1, such as at one of the sides, or in the middle of the back cover 5.

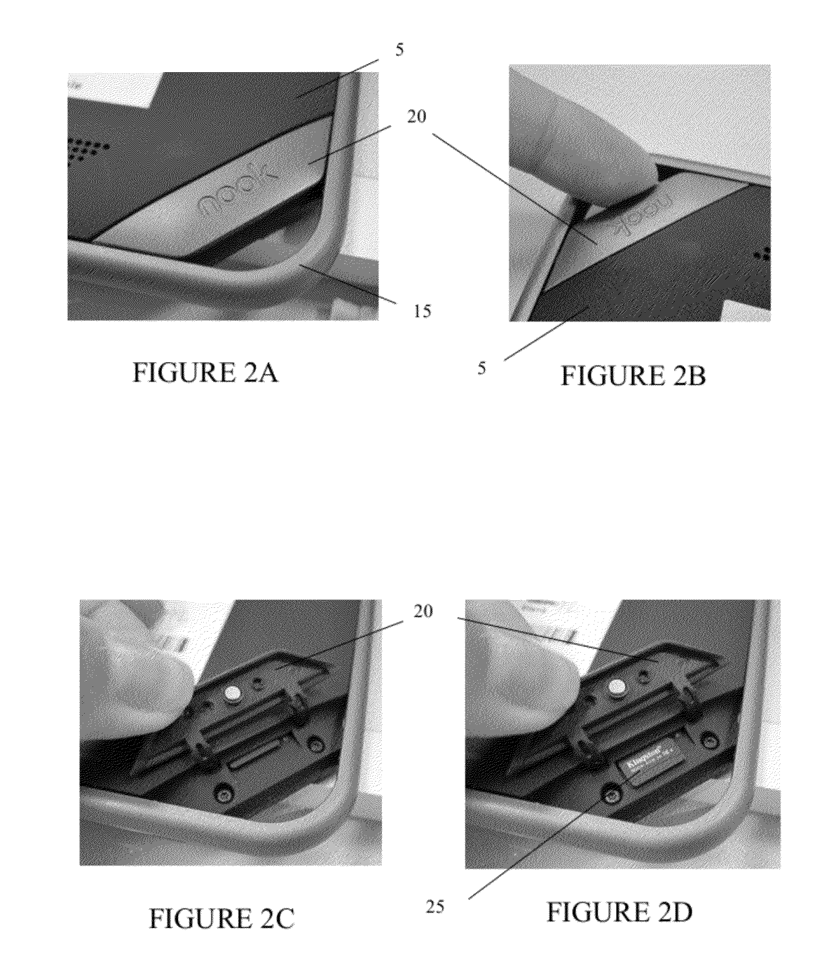

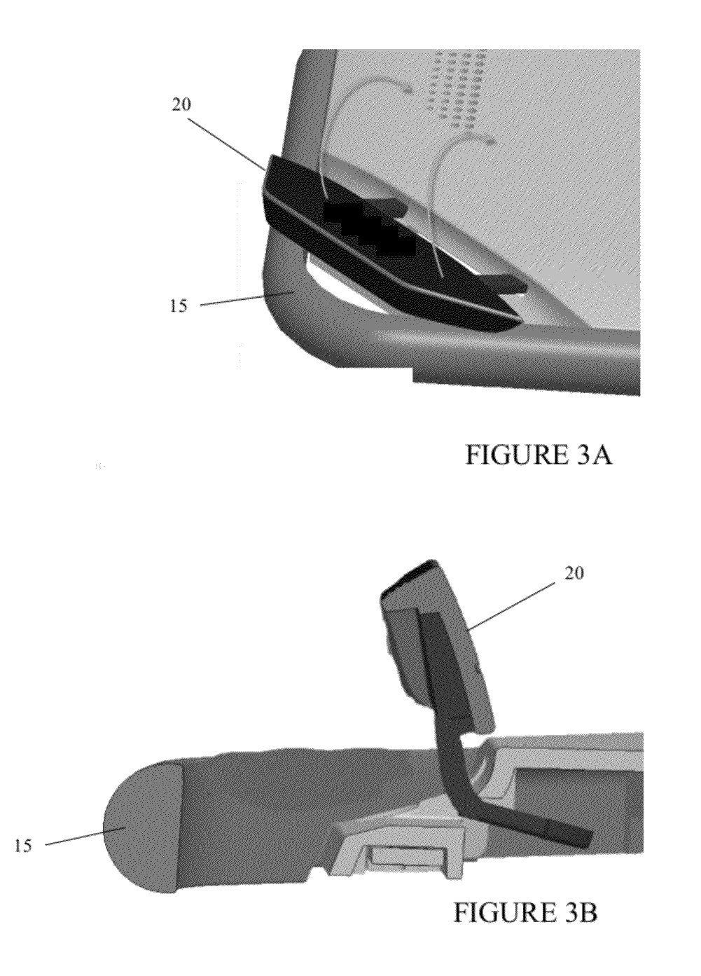

FIGS. 2A-2D depict the operation of the door 20 in accordance with an aspect of the present invention. As can be seen in FIGS. 2A and 2B, the gap 4 formed by the lanyard loop 15 provides a convenient location for a user to insert his or her finger to operate the door 20. By applying upward pressure, the user is able to release the door 20 from its securing mechanisms, to be described in more detail below. This allows the door 20 to be raised and folded backward as illustrated, e.g., in FIGS. 2C, 2D, 3A and 3B, exposing a tray for a memory device 25, such as a Secure Digital (SD) memory card.

As can be seen in FIGS. 2C and 2D, opening the door 20 exposes the tray for the memory device 25. Once the door is in the open position, the memory device 25 can be prepared for removal by, e.g., sliding the memory device forward, i.e., in the direction of the arrow in FIG. 2C, so that it is in the position shown in FIG. 2D, which makes it easy to remove by lifting it out of the device 1. The positions shown in FIGS. 2C and 2D would be reversed for inserting the memory card 25, i.e., sliding it into the tray. As will be appreciated by those skilled in the art, the door can act as a door to any interior compartment holding a variety of devices such as a subscriber identity module (SIM) card, a battery, or the like.

FIGS. 3A and 3B illustrate the operation of opening the door 20 to access the memory card, i.e., by pulling the door 20 out and then back to obtain the open position shown in FIGS. 2C and 2D. As can be seen in the figures, the door 20 is attached to the device back cover 5 by means of two flexible door anchors 30. The two door anchors 30 serve to retain the door 20 in back cover 5, even when the door is in an open position. The door anchors 30 are made of flexible material, such as rubber, plastic or other similar material, that can bend back to allow for the door 20 to be raised when accessing the memory device 25.

In opening the door 20, the door 20 is pulled up and out, but is retained in the housing by the anchors 30, as will be discussed in more detail below. The door pulls out, as shown in FIG. 3A, with the anchors 30 being pulled out of apertures 60 formed in a housing of the back cover 5. As can be seen in the cross-sectional view of FIG. 3B, the elastic characteristic of the anchors allows them to be bent back to permit the cover 20 to be opened far enough to allow access to the tray for the memory device 25. The anchors 30 are caused to bend by the upward pressure of the finger on the cover 20, and by contacting, at a point along the length of the anchor 30, the top edges of each of the apertures 60, as can be seen in FIG. 3B.

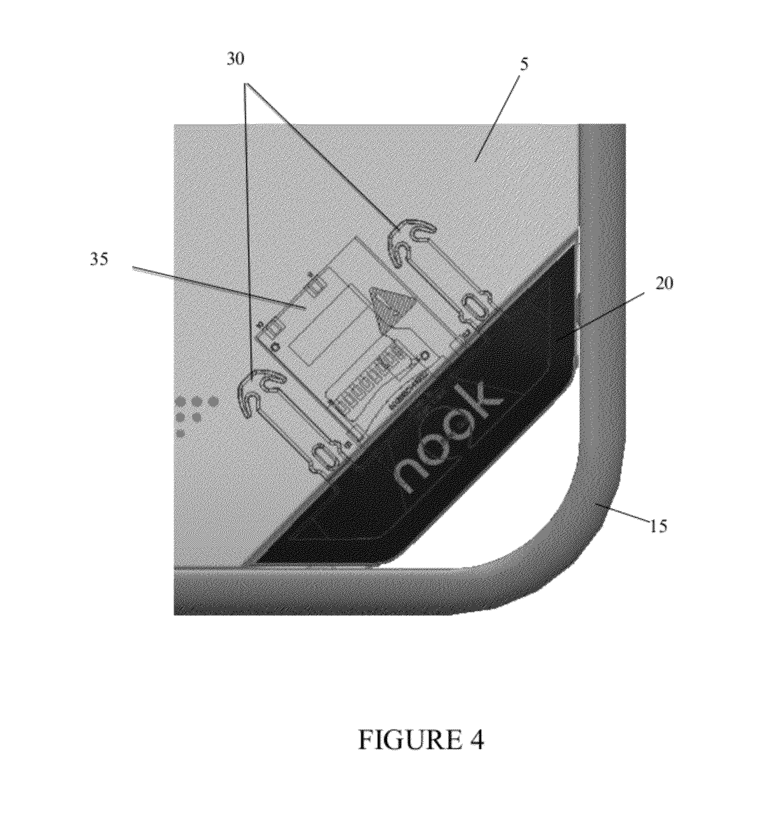

FIG. 4 is a partial cross section of the door 20 in a closed state. As illustrated in this figure, the two door anchors 30 serve to retain the door 20 in back cover 5. This figure further illustrates the tray 35 that hold the SD card. Also, as can be seen in FIG. 4, each door anchor includes bumps 33 and barbed ends 32. As seen in this Figure, the anchors 30 are disposed in an interior portion of cover 5, when cover 5 is installed on device 1. Anchors 30 are installed in cover 5 through apertures 60 in the cover 5 and are preferably placed on either side of the tray 35 that holds the SD card.

Bumps 33 on the body of anchor 30 help secure the door 20 in the closed state. The bumps 65 frictionally contact the inner walls of the apertures 60 to keep the door 20 from extending further out of cover 5, unless the frictional force of this contact is overcome by the user pulling the door with sufficient force. An opening 34 in the body of anchor 30 allows the material of the anchor 30 to compress, in particular at the points forming the bumps 65, when the door 20 is open or closed. The barbed ends 32 of anchors 30 prevent the door from becoming completely disengaged from cover 5 when the cover is in the open state.

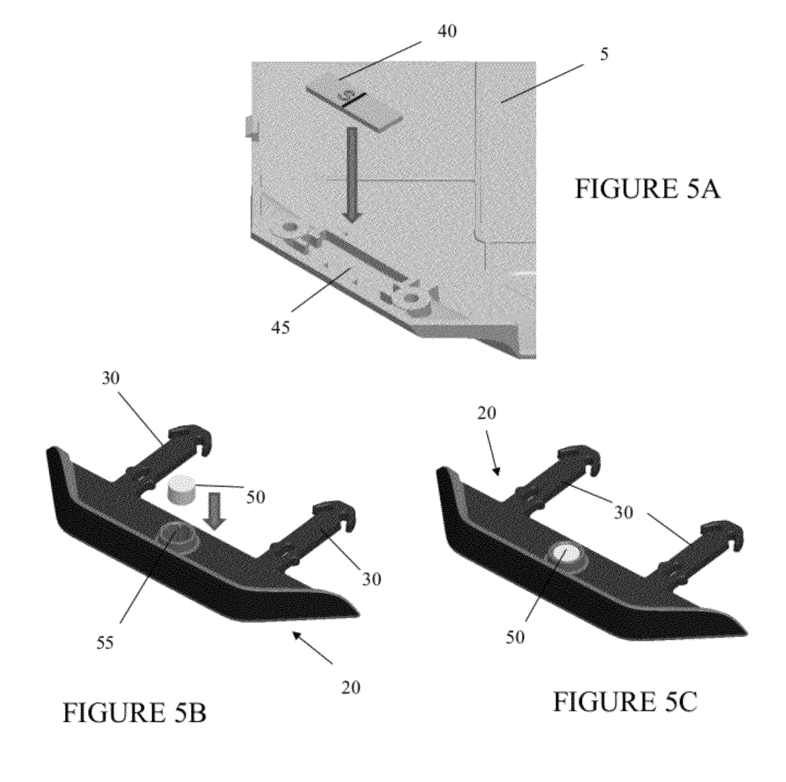

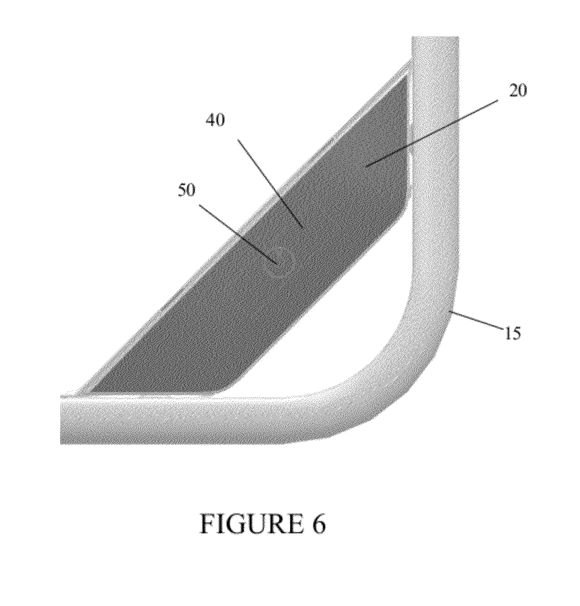

One of the mechanisms used in the present invention to secure the door 20 in a closed state is a magnet assembly. FIGS. 5A-5C and 6 illustrate the magnet assembly in accordance with an aspect of the present invention. A first portion of the magnet assembly, illustrated in FIG. 5A, comprises a first permanent magnet 40 that is disposed in a recess 45 in the back cover 5 of device 1. Installing the magnet 40 in this manner allows the magnet 40 to be hidden from the user.

A second portion of the magnet assembly comprises a second permanent magnet 50 that is disposed in a recess 55 in door 20. As can be seen in FIGS. 5B and 5C, the magnet 50 is installed into the recess 55 in the direction of the arrow in FIG. 5B.

As seen in FIG. 6, when the door is in a closed position, the two magnets 40 and 50 align, attract, and serve to close and keep door 20 closed. If the magnets 40/50 become accidentally disengaged, the bumps 33 of the anchors 30 urge the cover to stay in the closed position.

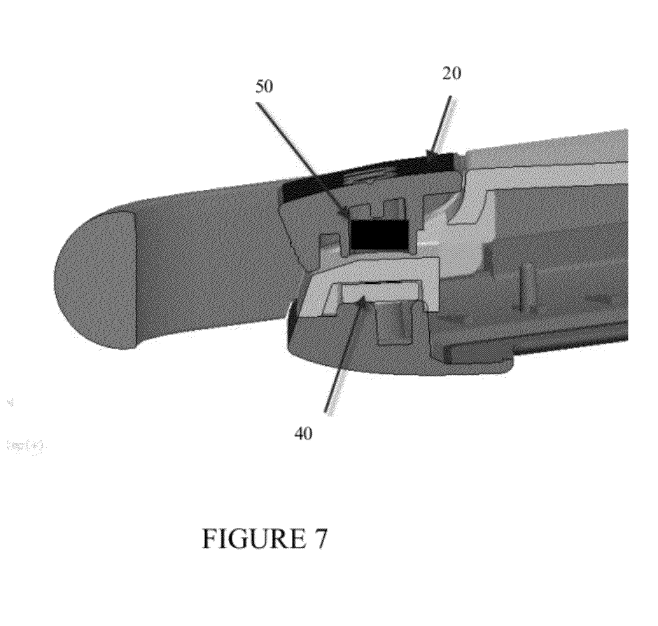

FIG. 7 illustrates a cross section of the door in a closed state showing the orientation of the magnets 40 and 50, and the recess 45, when the cover 20 is in the closed position.

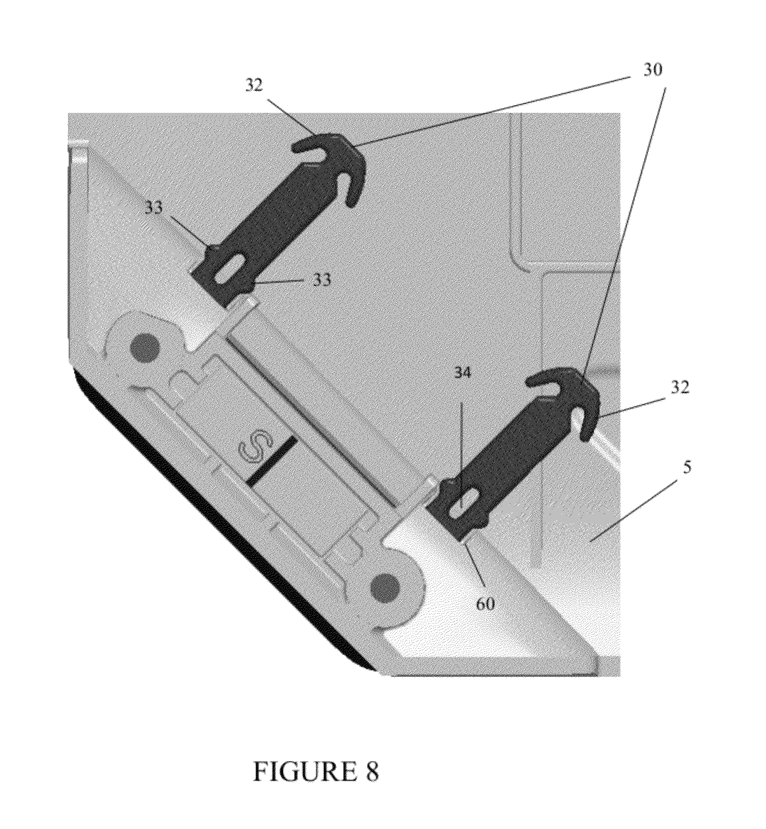

FIG. 8 further illustrates the door anchors 20 of the present invention. This Figure is a partial cross section, viewed from the bottom of the cover 5 and depicts the anchors 30 when the door 20 is in a closed state. As seen in this Figure, when cover 5 is installed on device 1, the anchors 30 are disposed in an interior portion of cover 5 through apertures 60. The bumps 33 on the body of anchor 30 function as detents and help secure the door 20 in the closed state by providing resistance when the door is opened or closed. If the magnets 40 and 50 become accidentally disengaged from one another, the bumps 33 serve to prevent the door 20 from extending further out of cover 5. As discussed above, the barbed ends 32 of anchors 30 prevent the door from becoming completely disengaged from cover 5. The opening 34 in each anchor 30 allows the elastic material, e.g., rubber to compress when the door is opened or closed.

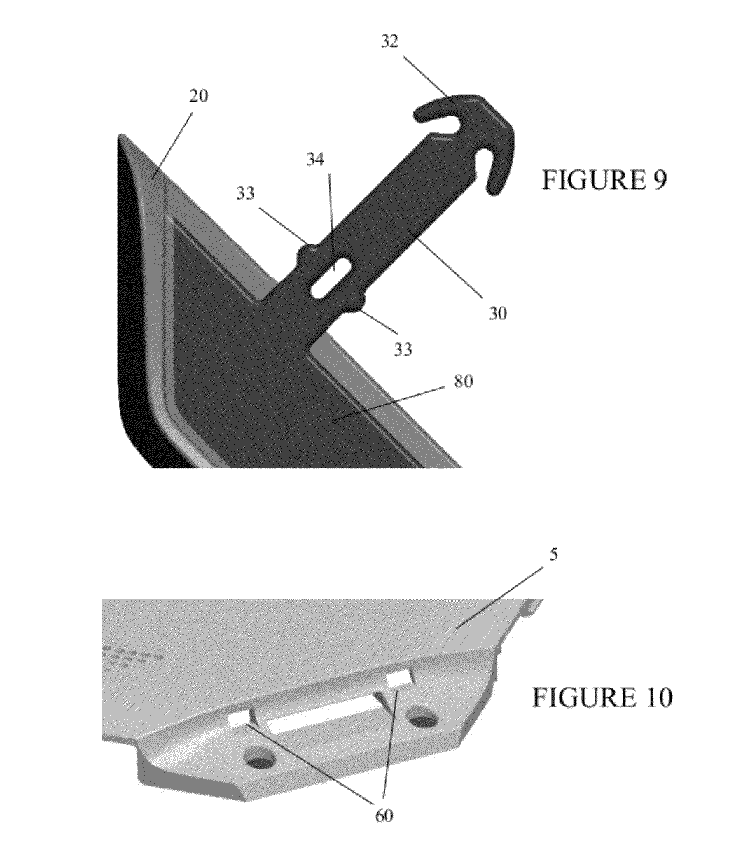

FIG. 9 is a further view of the door anchors. As seen in this view, the anchors 30 can be formed from a single sheet of elastic material, e.g., rubber. The body of the sheet 80 is attached to the underside of door 20. FIG. 10 further illustrates the portion of the housing that includes the apertures 60 in the back cover 5. As has been described above, the apertures 60 permit insertion of the anchors 30 of the door 20 into the back cover 5.

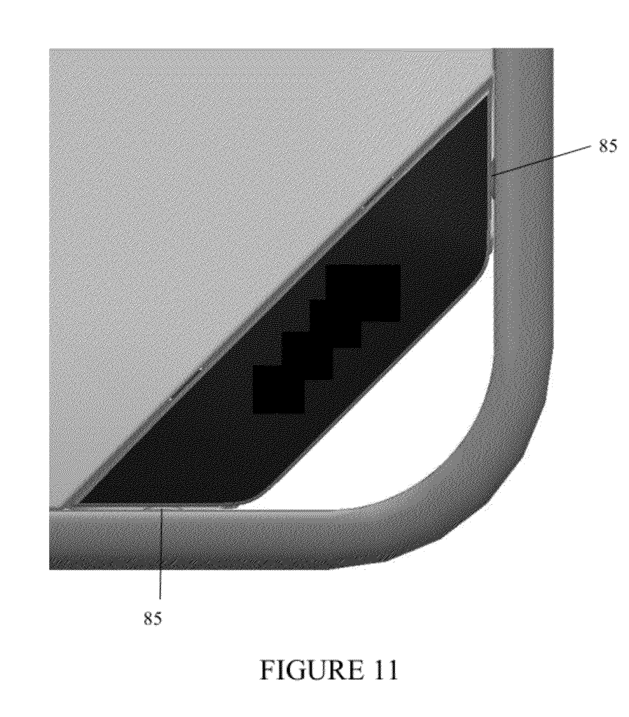

FIG. 11 depicts the door 20 in the closed condition and also shows an additional feature in accordance with an aspect of the present invention—projections 90 formed on the frame in the lanyard loop area. These projections 90 formed on the frame tend to force the door 20 toward an open state when the magnets 40/50 are disengaged by lifting the door 20. The projections impart an urging force against the sides of the door 20, the friction of which also needs to be overcome to open the door 20.

By virtue of the disclosed door 20 and associated structure, a secure cover for a compartment, such as a compartment for an SD memory card, can be achieved with light weight, and ease of operation by the user.

Although the present invention has been described in relation to particular embodiments thereof, many other variations and other uses will be apparent to those skilled in the art. It is preferred, therefore, that the present invention be limited not by the specific disclosure herein, but only by the scope of the following claims.

What is claimed is:

1. A door assembly for enclosing a compartment of a portable electronic device, the door assembly comprising:
a door cover, operable to selectively provide access to the compartment;
anchors, affixed to the door cover, configured to retain the door in a cover portion of the portable electronic device; and
a permanent magnet, disengageably mounted in the door cover, the permanent magnet operable to maintain the door in a closed state with respect to the compartment.

2. The door assembly according to claim 1, wherein the anchors comprise lengthwise protrusions associated with the door cover that prevent the door cover from completely disengaging from the cover portion of the portable electronic device.

3. The door assembly according to claim 2, wherein the anchors are formed from an elastic material.

4. The door assembly according to claim 2, wherein the anchors comprise bumps formed on a portion proximal to the door cover, the bumps forming detents that contact and impart a frictional force to a recessed portion of the cover portion when the door cover is in a closed state with respect to the compartment.

5. The door assembly according to claim 4, wherein an opening in each of the anchors between the bumps facilitates the anchors to compress when the door is being opened or closed.

6. The door assembly according to claim 2, wherein the anchors comprise barbed ends formed on a portion distal to the door cover, the barbed ends maintaining the door assembly in the cover portion when the door cover is in an open state.

7. The door assembly according to claim 2, wherein the recessed portion comprises apertures in the back cover.

8. The door assembly according to claim 2, wherein the anchors have a substantially flat profile and mate with apertures formed in the housing.

9. The door assembly according to claim 1, wherein the disengageably mounted permanent magnet in the door cover is operable to maintain the door in a closed state by magnetic attraction to another permanent magnet located in the cover portion of the portable electronic device.

10. The door assembly according to claim 9, wherein the disengageably mounted permanent magnet in the door cover and the permanent magnet located in the cover portion of the portable electronic device are aligned with one another when the door is in a closed state and the magnetic attraction between them maintains the door in the closed state by magnetic attraction.

11. The door assembly according to claim 1, wherein the device further comprises a frame around a periphery of the cover portion, an inner portion of the frame comprising dimples operable to hold the door cover in the closed state.

12. The door assembly according to claim 1, wherein the device further comprises a frame around a periphery of the cover portion, the door assembly being located within a gap formed between the frame and a corner of the cover portion.

13. The door assembly according to claim 1, wherein the compartment houses one from among the group consisting of an memory SD card, a SIM card and a battery.

14. The door assembly according to claim 1, wherein the anchors are formed of a single piece of elastic material affixed to the door cover.

15. The door assembly according to claim 1, wherein the anchors are substantially completely within the cover portion when the door is in the closed state and partially withdrawn from the cover portion when the door is in the open state.

16. The door assembly according to claim 1, wherein the anchors are positioned on the door cover so as to be placed on either side of the compartment.

17. A housing for a portable electronic device, the housing comprising:
a cover portion of the portable electronic device forming at least a substantial part of a surface of the portable electronic device;
a rim formed around a periphery of the cover portion, a gap being formed between the cover portion and the rim at least one point along the periphery;
a compartment formed in the cover portion; and
a door assembly for selectively enclosing the compartment, the door assembly comprising:
a door cover, operable to selectively provide access to the compartment;
anchors, affixed to the door cover, configured to retain the door in a cover portion of the portable electronic device; and
a permanent magnet, disengageably mounted in the door cover, the permanent magnet operable to maintain the door in a closed state with respect to the compartment.

18. The housing according to claim 17, wherein the anchors comprise lengthwise protrusions associated with the door cover that prevent the door cover from completely disengaging from the cover portion of the portable electronic device.

19. The housing according to claim 18, wherein the anchors are formed from an elastic material.

20. The housing according to claim 18, wherein the anchors comprise bumps formed on a portion proximal to the door cover, the bumps forming detents that contact and impart a frictional force to a recessed portion of the cover portion when the door cover is in a closed state with respect to the compartment.

21. The housing according to claim 20, wherein an opening in each of the anchors between the bumps facilitates the anchors to compress when the door is being opened or closed.

22. The housing according to claim 18, wherein the anchors comprise barbed ends formed on a portion distal to the door cover, the barbed ends maintaining the door assembly in the cover portion when the door cover is in an open state.

23. The housing according to claim 18, wherein the recessed portion comprises apertures in the back cover.

24. The housing according to claim 18, wherein the anchors have a substantially flat profile and mate with apertures formed in the housing.

25. The housing according to claim 17, wherein the disengageably mounted permanent magnet in the door cover is operable to maintain the door in a closed state by magnetic attraction to another permanent magnet located in the cover portion of the portable electronic device.

26. The housing according to claim 25, wherein the disengageably mounted permanent magnet in the door cover and the permanent magnet located in the cover portion of the portable electronic device are aligned with one another when the door is in a closed state and the magnetic attraction between them maintains the door in the closed state by magnetic attraction.

27. The housing according to claim 17, wherein an inner portion of the frame comprises dimples operable to hold the door cover in the closed state.

28. The housing according to claim 17, wherein the door assembly is located within a gap formed between the frame and a corner of the cover portion.

29. The housing according to claim 17, wherein the compartment houses one from among the group consisting of an memory SD card, a SIM card and a battery.

30. The housing according to claim 17, wherein the anchors are formed of a single piece of elastic material affixed to the door cover.

31. The housing according to claim 17, wherein the anchors are substantially completely within the cover portion when the door is in the closed state and partially withdrawn from the cover portion when the door is in the open state.

32. The housing according to claim 17, wherein the anchors are positioned on the door cover so as to be placed on either side of the compartment.

33. A door assembly for enclosing a compartment of a portable electronic device, the door assembly comprising:
a door cover, operable to selectively provide access to the compartment by partial detachment of the door cover from the compartment;
anchors, affixed to the door cover, configured to retain the door in a cover portion of the portable electronic device, the anchors including bumps along outer edges of each anchor to provide a frictional force operable to maintain the door in a closed state with respect to the compartment; and
a permanent magnet, disengageably mounted in the door cover, the permanent magnet operable to maintain the door in a closed state with respect to the compartment,
the door cover being operable to be changed from the closed state to an open state by application of upward pressure, by a user to the door cover, of sufficient force to overcome the maintaining forces provided by the bumps and the permanent magnet.
